(19) United States
(12) Patent Application Publication
(10) Pub. No.: US 2023/0143539 A1
(43) Pub. Date: May 11, 2023

(54) METHOD OF MANUFACTURING SEMICONDUCTOR DEVICES AND CORRESPONDING SEMICONDUCTOR DEVICE

(71) Applicant: STMicroelectronics S.r.l., Agrate Brianza (MB) (IT)

(72) Inventors: Michele DERAI, Milano (IT); Pierangelo MAGNI, Villasanta (IT)

(73) Assignee: STMicroelectronics S.r.l., Agrate Brianza (MB) (IT)

(21) Appl. No.: 17/977,137

(22) Filed: Oct. 31, 2022

(30) Foreign Application Priority Data
Nov. 10, 2021 (IT) 102021000028553

(51) Int. Cl. H01L 23/48; H01L 23/29; H01L 23/31; H01L 23/495; H01L 21/56; H01L 21/60; H01L 21/768

(52) U.S. Cl. CPC H01L 23/481; H01L 23/29; H01L 23/3135; H01L 23/49503; H01L 21/565; H01L 21/60; H01L 21/76877; H01L 2021/60292

(57) ABSTRACT

A semiconductor die is arranged on a substrate and an encapsulation of laser direct structuring (LDS) material is molded onto the semiconductor die. A through mold via (TMV) extends through the encapsulation. This TMV includes a collar section that extends through a first portion of the encapsulation from an outer surface to an intermediate level of the encapsulation, and a frusto-conical section that extends from a bottom of the collar section through a second portion of the encapsulation. The collar section has a first cross-sectional area at the intermediate level. The first end of the frusto-conical section has a second cross-section area at the intermediate level. The second cross-sectional area is smaller than the first cross-sectional area. The TMV can have an aspect ratio which is not limited to 1:1.

### PRIORITY CLAIM

This application claims the priority benefit of Italian Application for Patent No. 102021000028553, filed on Nov. 10, 2021, the content of which is hereby incorporated by reference in its entirety to the maximum extent allowable by law.

### TECHNICAL FIELD

The description relates to semiconductor devices.

Semiconductor devices in Quad-Flat No-leads (QFN) packages may be exemplary of devices where embodiments can be advantageously applied.

### BACKGROUND

Laser direct structuring (LDS) technology (oftentimes referred to also as direct copper interconnect (DCI) technology) has been recently proposed to replace conventional wire bonding in die-to-lead electrical connections in semiconductor devices.

In LDS technology as currently used today, after laser structuring (activation) in an LDS material, electrical conductivity of formations such as vias and lines or traces is facilitated via plating (e.g., electro-less metallization followed by galvanic deposition) to reach a metallization thickness of tens of microns of metal material such as copper.

An issue arising when applying laser direct structuring in providing electrical connections in semiconductor devices such as QFN devices lies in the nearly 1:1 aspect ratio constraint related to the formation (e.g., electroplating) of frusto-conical vias.

The designation “aspect ratio” is currently adopted to denote the ratio of the width to the height of an image or an object in general.

Aspect ratio constraints in forming vias affect via landing on leads for fine pitch leadframes (0.4 mm or less) or for packages where molding thickness is high (so-called “slug-up” QFNs, for instance). An increase in via diameter can undesirably lead to undesired misalignment with respect to the leads and may result in metal short-circuits (“shorts”).

There is a need in the art to contribute in adequately dealing with such an aspect ratio issue.

### SUMMARY

One or more embodiments relate to a method.

One or more embodiments relate to a corresponding semiconductor device.

Semiconductor devices in a Quad-Flat No-leads (QFN) package may be exemplary of devices where embodiments can be advantageously applied.

One or more embodiments provide an approach in producing through mold vias (TMVs) that adequately addresses the aspect ratio issue discussed in the foregoing.

One or more embodiments improve manufacturability and package miniaturization.

For instance, embodiments as discussed herein improve manufacturability of fine-pitch Quad-Flat No-leads (QFN) packages using laser direct structuring (LDS) technology.

Examples as disclosed herein involve providing through mold vias comprising an upper collar, larger than a bottom via portion.

Examples as disclosed herein involve laser machining a through mold via in two ablation steps, to form first a collar recess and then a frusto-conical via extending from a bottom of the collar recess.

Examples as disclosed herein offer one or more of the following advantages: the formation of a collar facilitates creating vias that are not constrained by a 1:1 aspect ratio, e.g., creating vias with a diameter smaller than mold cap (encapsulation) thickness; a simpler molding process derives from the possibility of avoiding thin mold caps; a simpler metallization process (e.g., Cu plating) can be implemented; molding compound downsizing facilitates obtaining vias with a (global) aspect ratio no longer limited to 1:1 (that is, “lean” through mold vias can be produced having a height higher than their width); and no additional process steps are involved over conventional package solutions based on LDS technology.

### BRIEF DESCRIPTION OF THE DRAWINGS

One or more embodiments will now be described, by way of example only, with reference to the annexed figures, wherein:

FIG. 1 is a cross-sectional view through a semiconductor device exemplary of the possible application of LDS technology to manufacturing semiconductor devices,

FIG. 2 is a cross-sectional view through a semiconductor device exemplary of manufacturing semiconductor devices according to embodiments of the present description,

FIG. 3 is a plan view essentially along line III-III in FIG. 2 further detailing manufacturing semiconductor devices according to embodiments of the present description, and

FIGS. 4A to 4H are exemplary of a possible sequence of steps in manufacturing semiconductor devices according to embodiments of the present description.

### DETAILED DESCRIPTION

Corresponding numerals and symbols in the different figures generally refer to corresponding parts unless otherwise indicated.

The figures are drawn to clearly illustrate the relevant aspects of the embodiments and are not necessarily drawn to scale.

The edges of features drawn in the figures do not necessarily indicate the termination of the extent of the feature.

In the ensuing description, various specific details are illustrated in order to provide an in-depth understanding of various examples of embodiments according to the description. The embodiments may be obtained without one or more of the specific details, or with other methods, components, materials, etc. In other cases, known structures, materials, or operations are not illustrated or described in detail so that various aspects of the embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment”, “in one embodiment”, or the like, that may be present in various points of the present description do not necessarily refer exactly to one and the same embodiment. Furthermore, particular configurations, structures, or characteristics may be combined in any adequate way in one or more embodiments.

The headings/references used herein are provided merely for convenience and hence do not define the extent of protection or the scope of the embodiments.

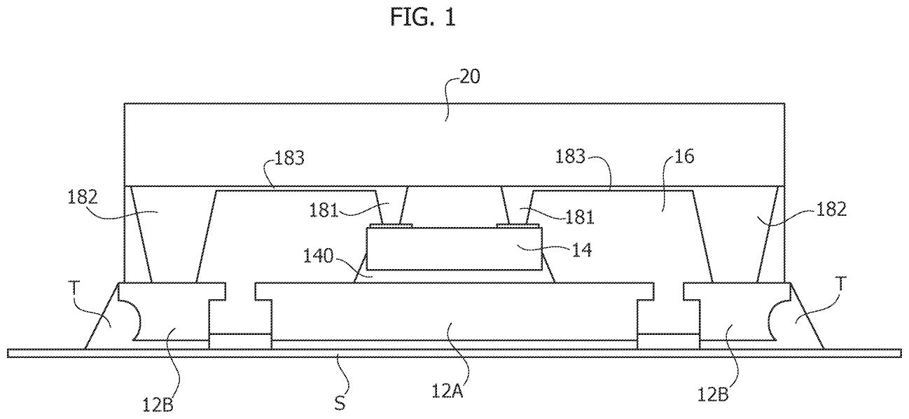

FIG. 1 is representative of a possible application of laser direct structuring (LDS) technology in providing die-to-lead electrical coupling in a semiconductor device.

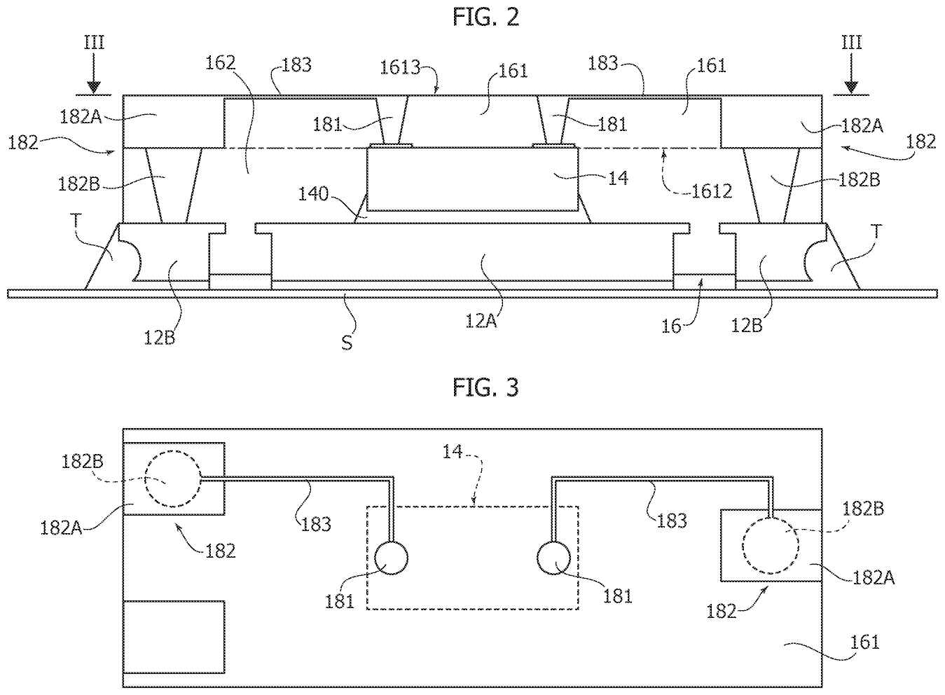

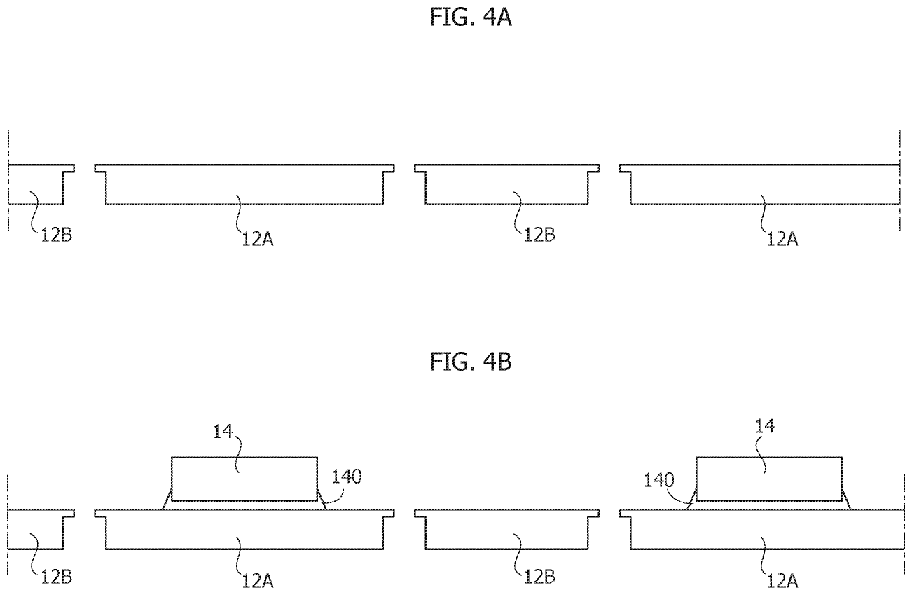

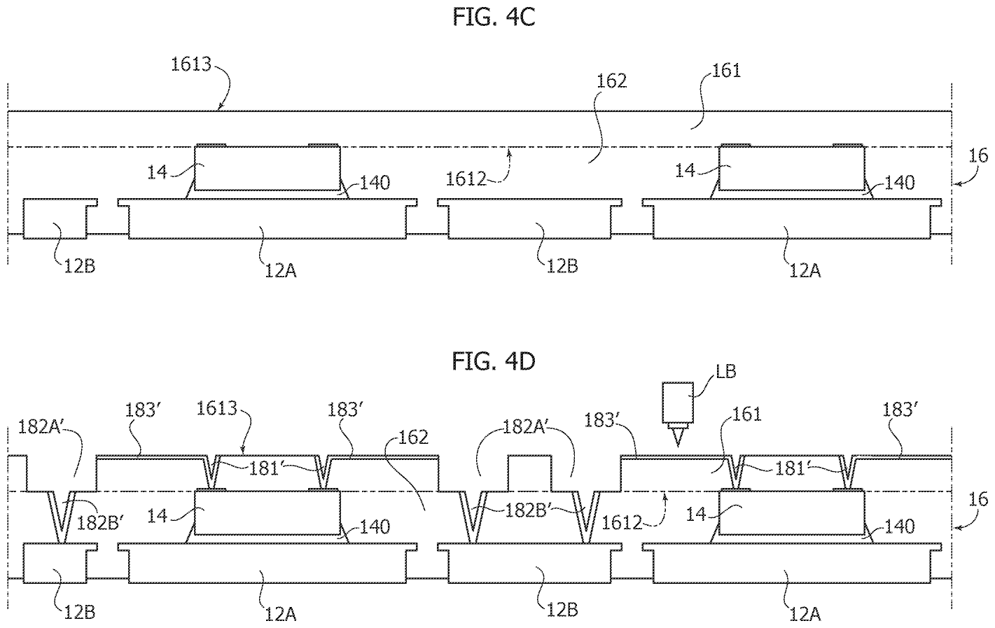

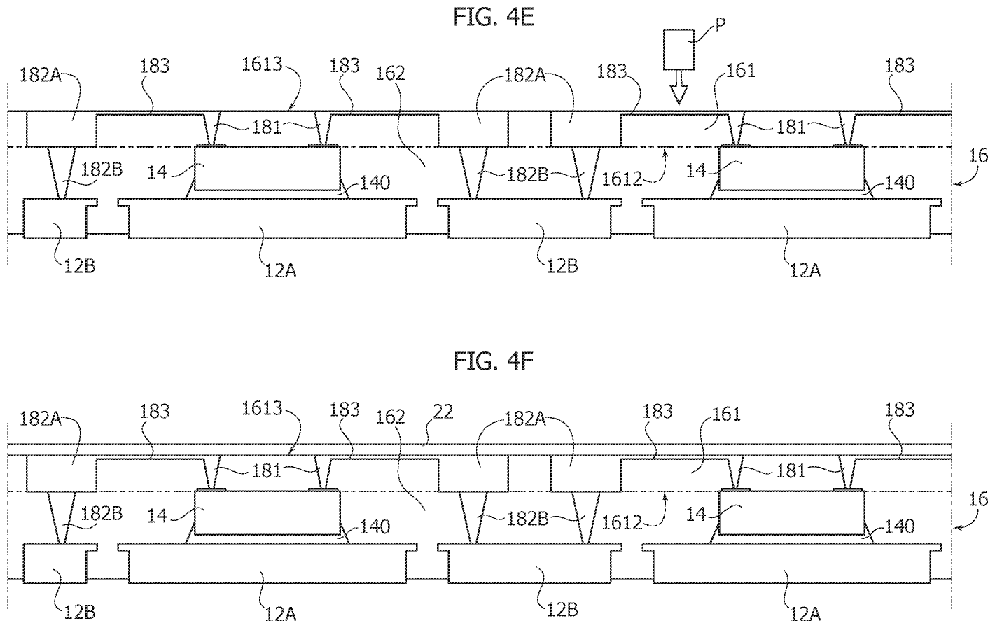

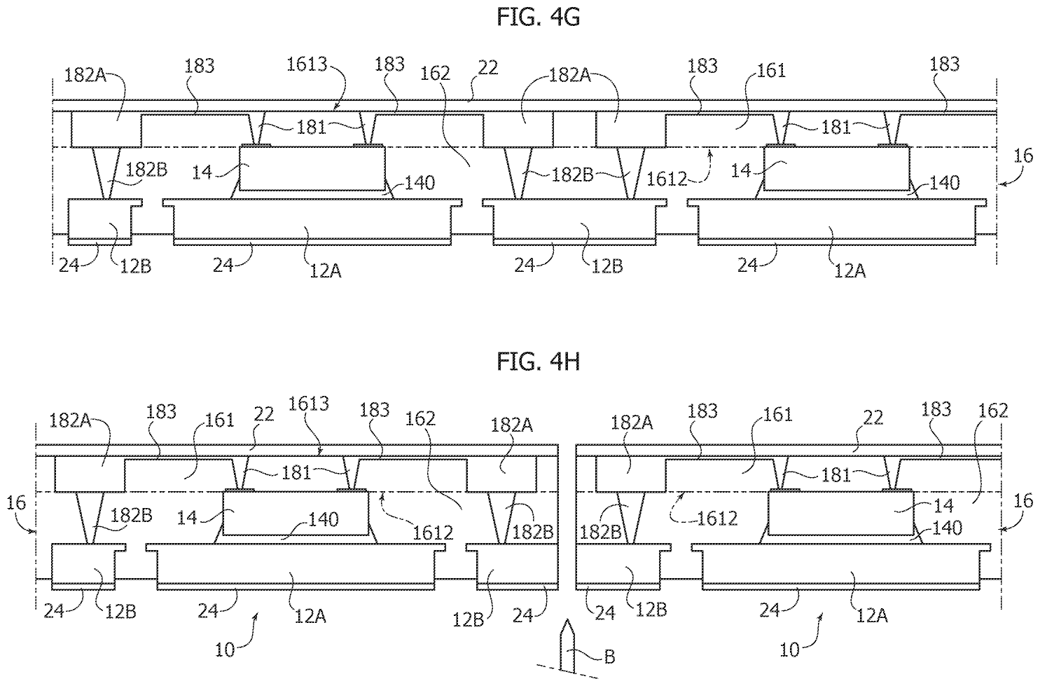

FIG. 1 (and FIGS. 2 and 3 as well) refer for simplicity to a single device. In fact, devices as illustrated in these figures are currently manufactured in an assembly flow of plural semiconductor devices that are manufactured simultaneously and finally separated into individual devices 10 via a singulation step as exemplified in FIG. 4H.

FIG. 1 refers to a (single) device comprising a leadframe having one or more die pads 12A (only one is illustrated for simplicity) onto which respective semiconductor integrated circuit chips or dice 14 are mounted (for instance attached using die attach material 140) with an array of leads 12B around the die pad 12A and the semiconductor chips or dice 14.

As used herein, the terms chip/s and die/dice are regarded as synonymous.

The designation “leadframe” (or “lead frame”) is currently used (see, for instance the USPC Consolidated Glossary of the United States Patent and Trademark Office) to indicate a metal frame that provides support for an integrated circuit chip or die as well as electrical leads to interconnect the integrated circuit in the die or chip to other electrical components or contacts.

Essentially, a leadframe comprises an array of electrically-conductive formations (or leads, e.g., 12B) that from an outline location extend inwardly in the direction of a semiconductor chip or die (e.g., 14) thus forming an array of electrically-conductive formations from a die pad (e.g., 12A) configured to have at least one semiconductor chip or die attached thereon. This may be via conventional means such as a die attach adhesive (a die attach film (DAF) 140 for instance).

A device as illustrated in FIG. 1 is intended to be mounted on a substrate S such as a printed circuit board (PCB), using solder material T, for instance.

For simplicity, in FIG. 1 (and FIGS. 2 and 3 as well) a single die pad 12A is illustrated having a single chip 14 attached thereon. In various embodiments, plural chips 14 can be mounted on a single die pad 12A or plural die pads.

Laser direct structuring (LDS), oftentimes referred to also as direct copper interconnection (DCI) technology, is a laser-based machining technique now widely used in various sectors of the industrial and consumer electronics markets, for instance for high-performance antenna integration, where an antenna design can be directly formed onto a molded plastic part. In an exemplary process, the molded parts can be produced with commercially available insulating resins that include additives suitable for the LDS process; a broad range of resins such as polymer resins like PC, PC/ABS, ABS, LCP are currently available for that purpose.

In LDS, a laser beam can be used to transfer (“structure”) a desired electrically-conductive pattern onto a plastic molding that may then be subjected to metallization to finalize a desired conductive pattern.

Metallization may involve electroless plating followed by electrolytic plating.

Electroless plating, also known as chemical plating, is a class of industrial chemical processes that creates metal coatings on various materials by autocatalytic chemical reduction of metal cations in a liquid bath.

In electrolytic plating, an electric field between an anode and a workpiece, acting as a cathode, forces positively charged metal ions to move to the cathode where they give up their charge and deposit themselves as metal on the surface of the work piece.

Reference is made to United States Patent Application Publication Nos. 2018/0342453 A1, 2019/0115287 A1, 2020/0203264 A1, 2020/0321274 A1, 2021/0050226 A1, 2021/0050299 A1, 2021/0183748 A1, and/or 2021/0305203 A1 (all assigned to the same assignee of the present application, and which are incorporated herein by reference) which are exemplary of the possibility of applying LDS technology in manufacturing semiconductor devices.

For instance, LDS technology facilitates replacing wires, clips or ribbons with lines/vias created by laser beam processing of an LDS material followed by metallization (growing metal such as copper via a plating process, for instance).

Still referring to FIG. 1, an encapsulation 16 of LDS material can be molded onto the leadframe 12A, 12B having the semiconductor chip or die 14 mounted thereon.

Electrically conductive die-to-lead coupling formations can be provided (in a manner known per se: see the commonly assigned applications cited in the foregoing, for instance) in the LDS material 16 (once consolidated, e.g., via thermosetting).

As illustrated in FIG. 1, these die-to-lead coupling formations comprise: first vias 181 and second vias 182 and electrically-conductive lines or traces 183. The first vias 181 extend through the LDS encapsulation 16 between the top (front) surface 16A of the LDS encapsulation 16 (opposed the leadframe 12A, 12B) and electrically-conductive pads (not visible for scale reasons) at the front or top surface of the chip or die 14. The second vias 182 extend through the LDS encapsulation 16 between the top (front) surface 16A of the LDS encapsulation 16 and corresponding leads 12B in the leadframe. The electrically-conductive lines or traces 183 extend at the front or top surface 16A of the LDS encapsulation 16 and electrically couple selected ones of the first vias 181 with selected ones of the second vias 182 to provide a desired die-to-lead electrical connection pattern between the chip or die 14 and the leads 12B.

Providing the electrically conductive die-to-lead formations 181, 182, and 183 essentially involves structuring these formations in the LDS material 16, for instance, laser-drilling (blind) holes therein at the desired locations for the vias 181, 182, followed by growing electrically-conductive material (a metal such as copper, for instance) at the locations previously activated (structured) via laser beam energy.

As illustrated in FIG. 1, further encapsulation material 20 (this can be non-LDS material, e.g., a standard epoxy resin) can be molded onto the die-to-lead formations 181, 182, and 183 to complete the device package.

Further details on processing as discussed in the foregoing can be derived from the commonly-assigned patent application publications referred to in the foregoing, for instance.

Briefly, using LDS technology, through mold vias (TMVs) 181, 182 and traces 183 are created to electrically interconnect one or more semiconductor dice 14 to a leadframe (leads 12B) thereby replacing conventional wire bonding used for that purpose.

With LDS technology, the interconnection is created using laser structuring (to create vias and lines or traces) and metal plating is used to fill the laser-structured formations with metal such as copper.

Plating design rules allow only a nearly 1:1 aspect ratio (diameter vs. depth) for through mold blind vias, in order to have a proper metal (e.g., copper) filling of the vias.

As illustrated in FIG. 1, the (front or top) surface of the die 14 is usually at a higher level with respect to the leadframe (die pad 14A and leads 12B): as a consequence, the encapsulation 16 (molding compound layer) is thicker at the leadframe than at the die surface.

Being constrained to a nearly 1:1 aspect ratio, vias such as the vias 182 formed at the leads 12B may have proximal ends (opposite the leads 12B) that are undesirably large in comparison with the leads: for instance, these proximal ends (that is, the upper ends of the vias 182 in FIG. 1) may have a diameter larger than the lead width.

Package design is adversely affected by this fact, primarily when a fine pitch (close spacing) is desired for the leads 12B.

For instance, assuming a 1:1 aspect ratio for vias design, the (larger) diameter of frusto-conical vias such as the vias 182 intended to connect to leads 12B can be chosen considering the thickness of the die attach material (140 in FIG. 1) plus the thickness of the semiconductor chip (14 in FIG. 1) and the (minimum) thickness of the LDS encapsulation 16 (for instance, about 30 microns should be preferably kept on top of die 14).

This may result in an undesired constraint in so far as only thin dice 14 (in a thickness range of 70 to 150 microns, assuming a die attach material thickness of 15 to 25 microns) can avoid the risk of having too large a vias (top) diameter, with possible “fall out” of the vias from the leads (having a width of 200 to 300 microns).

In conventional arrangements as illustrated in FIG. 1, increasing the thickness of the LDS encapsulation 16 may result in a larger vias diameter with possible via-to-lead mismatches: vias with diameter dimensions close to the lead width will leave only a poor margin to keep vias within the leads without “going out” of the leads.

Reference is also made to U.S. patent application Ser. No. 17/872,893 (corresponding to Italian Patent Application 102021000020537) and U.S. patent application Ser. No. 17/872,774 (corresponding to Italian Patent Application 102021000020540), both assigned to the same assignee of the present application, incorporated herein by reference, and not yet available to the public at the time of filing of the present application. The patent applications disclose the possibility of extending the use of LDS processing from producing die-to-lead coupling formations as discussed in the foregoing to producing die-to-die coupling formations.

Issues similar to the issues discussed in the foregoing in connection with forming vias in die-to-lead coupling formations may thus arise when forming vias in die-to-die coupling formations.

While disclosed for simplicity in connection with forming vias in die-to-lead coupling formations, the examples herein can be advantageously applied to forming vias in die-to-die coupling formations. Similarly, these examples can be advantageously applied to vias in metallization-to-metallization level coupling formations as discussed in United States Patent Application Publication No. 2021/0183748 A1 (already cited).

Consequently, the embodiments herein shall not be regarded as limited to forming vias in die-to-lead coupling formations.

Throughout FIGS. 2, 3 and 4A to 4H parts or elements like parts or elements already discussed in connection with FIG. 1 are indicated with like reference symbols. A corresponding detailed description of these parts or elements and the way they can be produced will not be repeated for brevity.

In the examples to which FIGS. 2, 3 and 4A to 4H refer, through mold vias (TMVs) such as the vias 182 include two sections 182A and 182B formed in two superposed portions or layers 161 and 162 of the LDS encapsulation material 16.

In the examples to which FIGS. 2, 3 and 4A to 4H refer, a first section or portion of the vias 182 comprises an enlarged collar portion 182A formed into and through the first (outer) portion or layer 161 of the encapsulation of LDS material 16.

The first (outer) portion or layer 161 of the LDS material 16 is molded “on top” of the second (inner) portion or layer 162.

The first (outer) portion 161 thus extends from a (notional) intermediate plane 1612 of (or intermediate level 1612 within) the LDS encapsulation 16 up to a front or top surface 1613 of the (whole) LDS encapsulation 16.

A second section or portion 182B of the vias 182 comprises an (otherwise conventional) frusto-conical via formed through the second (inner) portion or layer 162 of the encapsulation of LDS material 16 that extends from the intermediate plane 1612 of the LDS encapsulation 16 towards the leadframe 12A, 12B.

The second portion 162 of the LDS encapsulation 16 is thus adjacent to the substrate 12A, 12B and borders on the first portion 161 at the intermediate plane 1612 of the encapsulation.

Like in the case of FIG. 1, in examples as presented in FIGS. 2 and 3, the vias 181 can be formed (in a manner known to those of skill in the art) through the first portion or layer 161 of the encapsulation of LDS material 16 molded onto the second portion or layer 162.

The vias 181 thus extend from the front or top surface 1613 of the (whole) LDS encapsulation to die pads (not visible for reasons of scale) at the front or top surface of the die 14.

As illustrated, the front or top surface of the die 14 lies (at least approximately) at or in the vicinity of the intermediate plane 1612. As used herein, the expression “approximately” refers to a technical feature within the technical tolerance of the method used to manufacture and/or measure it.

Electrically conductive lines or traces 183 can be formed (in a manner likewise known to those of skill in the art) at the front or top surface 1613 of the (whole) LDS encapsulation 16 to electrically couple the vias 181 to (the collars 182A of) the vias 182.

Examples as presented in FIGS. 2 and 3 use the collar 182A to reduce to the (sole) thickness of the second layer 162 the thickness of the LDS molding compound 16 through which the frusto-conical sections 182B of the vias 182 are formed.

The collars 182A formed in the first portion or layer 161 of the encapsulation 16 can be larger than the (larger diameter of the) vias 182B formed in the second portion or layer 162 of the encapsulation 16.

The size and dimensions of the collars 182A are largely independent of the sizes of the leads 12B. Collar dimensions can be (much) larger than the diameter of the frusto-conical vias 182B (ad measured in the plane 1612).

As visible, e.g., in FIG. 3, the collars 182A can be formed as parallelepiped notches “carved out” (by laser ablation, for instance) in the encapsulation layer 161.

This (also) facilitates plating metal (e.g., Cu) flow into the collars 182A to reach (and fill) the frusto-conical via portions 182B.

Vias 182 with a collar 182A may show (as a whole) a lean “cylindrical” shape (in contrast to the general frusto-conical shape of conventional vias 182 as illustrated in FIG. 1).

This facilitates achieving a larger bottom diameter of the vias 182 (at the leads 12B) while avoiding the limitations related to a 1:1 aspect ratio.

FIGS. 4A to 4H are exemplary of a possible sequence of steps in manufacturing semiconductor devices 10 based on the criteria discussed in connection with FIGS. 2 and 3.

Such a sequence involves laser machining a through mold via in two ablation steps, to form first a collar recess (e.g., a collar section 182A) and then a frusto-conical bottom via (e.g., a frusto-conical section 182B), that is forming first the enlarged collar section 182A and then forming the frusto-conical section 182B subsequent to forming the enlarged collar section 182A.

It will be otherwise appreciated that the sequence of FIGS. 4A to 4H is merely exemplary in so far as: one or more steps illustrated can be omitted, performed in a different manner (with other tools, for instance) and/or replaced by other steps; additional steps and may be added; and/or one or more steps can be carried out in a sequence different from the sequence illustrated.

Also, unless the context indicates differently, the individual steps illustrated in FIGS. 4A to 4H can be performed in a manner known to those of skill in the art, which makes it unnecessary to provide a more detailed description of these individual steps.

The sequence of steps of FIGS. 4A to 4H refers to the current practice of manufacturing semiconductor devices in an assembly flow of plural semiconductor devices that are manufactured simultaneously and finally separated into individual devices 10 via a singulation step (as exemplified in FIG. 4H).

FIG. 4A is exemplary of the provision of a (standard, e.g., metal) leadframe including die pads 12A as well as lead portions intended to provide arrays of leads 12B around the die pads 12A.

In that respect it is noted that the designation Quad-Flat No-leads (QFN) designation currently applied to devices such as the devices 10 illustrated herein refers primarily to the fact that, while including leads such as the leads 12B, these devices have no leads protruding radially from the package.

FIG. 4B is exemplary of semiconductor chips or dice 14 being attached at the die pads 12A. This may occur, as conventional in the art, via die attach material 140.

As noted, plural semiconductor chips or dice 14 can be arranged at the (front or top) surface of each die pad 12A: one chip or die 14 is illustrated here for simplicity.

FIG. 4C is exemplary of an encapsulation 16 of laser direct structuring (LDS) material being molded onto the structure of FIG. 4B.

The step of FIG. 4C can be implemented in a manner known per se (e.g., via compression molding of LDS molding compound including additives making it suited for laser activation as conventional in LDS processing).

FIG. 4C is thus exemplary of encapsulating the substrate (leadframe) 12A, 12B with the semiconductor chip 14 arranged thereon in an encapsulation 16 of laser direct structuring (LDS) material.

While in most instances applied as a single mass of LDS material, the encapsulation 16 can be regarded as comprising: an inner portion or layer (designated 162) having the chips or dice 14 embedded therein and extending up to the (notional) plane 1612 essentially flush with the front or top surface of the chips or dice 14, and an outer portion or layer (designated 161) molded “on top” of the inner layer 162 (and the chips or dice 14), with the outer portion or layer 161 extending from the plane 1612 to the front or top surface 1613 of the (whole) LDS encapsulation 16.

FIGS. 4D and 4E are exemplary of the application of laser beam energy LB to selected areas of the LDS material of the encapsulation 16 (FIG. 4D) followed by metallization P (e.g., electroless and electrolytic growth of conductive material such as copper—FIG. 4E) to form the first vias 181, the second vias 182A, 182B (182 as a whole), and electrically-conductive lines or traces 183. The first vias 181 extend through the first layer 161 of the LDS encapsulation 16 between electrically-conductive pads (not visible for scale reasons) provided at the front or top surface of the chips or dice 14 (essentially lying in the plane 1612) and the top (front) surface 1613 of the whole encapsulation (opposed the leadframe 12A, 12B). The second vias 182A, 182B (182 as a whole) extending through the LDS encapsulation 16 between the top (front) surface 1613 of the LDS encapsulation 16 and corresponding leads 12B in the leadframe, passing through the (notional) plane 1612. The electrically-conductive lines or traces 183 extend at the front or top surface 1613 of the LDS encapsulation 16 and electrically coupling selected ones of the first vias 181 with selected ones of the second vias 182 (collar portion 182A) to provide a desired die-to-lead electrical connection pattern between the chips or dice 14 and the leads 12B.

In FIG. 4D, reference numbers with accents (namely 181′, 182A′, 182B′ and 183′) are used to designate the result of applying laser beam energy (as exemplified by reference LB 4D) to the LDS encapsulation material 16.

In FIG. 4E, reference corresponding numbers without accents (namely 181, 182A, 182B and 183) are used to designate the result of a metallization step (as exemplified by reference P in FIG. 4E) of the locations 181′, 182A′, 182B′ and 183′ that facilitates electrical conductivity of the vias 181, 182 and the lines or traces 183.

As illustrated, applying LDS processing to the encapsulation 16 of LDS material comprises: applying laser beam energy LB to the LDS material 16 to provide therein laser-ablated regions for the collars 182A′ as well as for the vias 181′, 182B′ and the lines or traces 183′, and growing (via plating P, for instance) electrically conductive material at the laser-activated/ablated regions 181′, 182A′, 182B′ and 183′.

As illustrated in FIGS. 4D and 4E, providing the vias 182 comprises providing the two parts or portions thereof—namely the collar section 182A and the frusto-conical section 182B—formed in the two superposed layers 161 and 162 of the LDS encapsulation 16.

In terms of process flow, cavities for the collar sections 182A′ can be formed first—via laser ablation, for instance—through the outer layer 161 of the encapsulation of LDS material molded “on top” of the inner layer 162.

A frusto-conical section can then be formed (e.g., laser-drilled as 182B′) at and extending from the bottom of the collar section 182A′, with the frusto-conical section 182B′ extending through the inner layer 162 of the encapsulation 16 of LDS material from the notional plane 1612 (essentially flush with the front or top surface of the chip or die 14) to a respective lead 12B.

Metal material (e.g., copper) can then be grown into the sections 182A′ and 182B′ to facilitate electrical conductivity of the via 182 (collar 182A plus the frusto-conical via 182B) extending through the mold material 16 (layers 161 and 162) from the front or top surface 1613 of the (whole) LDS encapsulation 16 to the leads 12B passing through the (notional) intermediate plane 1612.

FIGS. 4D and 4E are thus exemplary of providing an electrical bonding pattern (vias 181, 182A, 182B plus lines or traces 183) between the semiconductor chip or chips 14 and selected ones of the leads 12B in the array of electrically conductive leads.

FIG. 4F is exemplary of the deposition of a passivation layer 22 at the front or top surface 1613 of the encapsulation 16. Passive components (not visible for simplicity) can be placed on the metallized lines or traces 183 at this stage.

FIG. 4G is exemplary of tin plating 24 applied at the back or bottom surface to facilitate mounting onto a substrate (see S in FIG. 2), e.g., via soldering material T.

FIG. 4H is exemplary of singulation (e.g., via a rotary blade B) to provide individual semiconductor devices 10.

Without prejudice to the underlying principles, the details and embodiments may vary, even significantly, with respect to what has been described by way of example only without departing from the extent of protection.

The claims are an integral part of the technical teaching provided herein in respect of the embodiments.

The extent of protection is determined by the annexed claims.

1. A method, comprising:
arranging at least one semiconductor die on a substrate;
molding an encapsulation of laser direct structuring (LDS) material onto the at least one semiconductor die arranged on the substrate, the encapsulation having an outer surface opposite the substrate and comprising a first portion of the encapsulation between the outer surface and an intermediate level in the encapsulation as well as a second portion of the encapsulation between the substrate and said intermediate level, wherein the second portion borders the first portion at said intermediate level; and
providing at least one electrically conductive via extending through a thickness of the encapsulation, wherein the at least one electrically conductive via comprises:
a collar section extending through the first portion of the encapsulation from the outer surface to the intermediate level, the collar section having a cross-sectional area at the intermediate level; and
a frusto-conical section extending through the second portion of the encapsulation from a first end at the intermediate level to a second end away from the intermediate level;
wherein the first end at the intermediate level has a first diameter and has an area smaller than a cross-sectional area of the collar section at the intermediate level; and
wherein the second end away from the intermediate level has a second diameter that is smaller than the first diameter.

2. The method of claim 1, wherein providing the at least one electrically conductive via comprises:
forming the collar section; and
forming the frusto-conical section subsequent to forming the collar section.

3. The method of claim 1, wherein an aspect ratio of the frusto-conical section is approximately equal to 1:1.

4. The method of claim 1, wherein a front surface of the at least one semiconductor die that is opposite to the substrate lies at least approximately at the intermediate level.

5. The method of claim 4, further comprising forming at least one frusto-conical electrically conductive via extending through the first portion from the outer surface of the encapsulation to the front surface of the at least one semiconductor die.

6. The method of claim 1, wherein the substrate comprises a die pad of a leadframe including an array of electrically conductive leads around the die pad, the method further comprising connecting said at least one electrically conductive via to at least one lead in the array of electrically conductive leads.

7. The method of claim 6, further comprising:
forming at least one frusto-conical electrically conductive via extending through the first portion from the outer surface of the encapsulation to a front surface of the at least one semiconductor die; and
forming at least one linear electrically conductive formation extending at the outer surface of the encapsulation and electrically connected to said at least one frusto-conical electrically conductive via and further connected to the collar section of the at least one electrically conductive.

8. The method of claim 1, further comprising:
applying laser beam energy to at least one selected location of the encapsulation of LDS material; and
growing metal material onto said at least one selected location of the encapsulation of LDS material to which laser beam energy has been applied.

9. The method of claim 8, wherein said growing metal material comprises:
electroless growing first metal material onto said at least one selected location of the encapsulation of LDS material to which laser beam energy has been applied; and
electrolytic growing second metal material onto the first metal material.

10. A device, comprising:
at least one semiconductor die arranged on a substrate;
an encapsulation of laser direct structuring (LDS) material molded onto the at least one semiconductor die, the encapsulation having an outer surface opposite the substrate and comprising a first portion of the encapsulation between the outer surface and an intermediate level in the encapsulation as well as a second portion of the encapsulation between the substrate and said intermediate level, wherein the second portion borders the first portion at said intermediate level; and
at least one electrically conductive via extending through the encapsulation of LDS material, wherein the at least one electrically conductive via comprises:
a collar section extending through the first portion of the encapsulation from the outer surface to the intermediate level, the collar section having a cross-sectional area at the intermediate level; and
a frusto-conical section extending through the second portion of the encapsulation from a first end at the intermediate level to a second end away from the intermediate level;
wherein the first end at the intermediate level has a first diameter and an area smaller than a cross-sectional area of the collar section at the intermediate level; and
wherein the second end away from the intermediate level has a second diameter that is smaller than the first diameter.

11. The device of claim 10, wherein the frusto-conical section has an aspect ratio approximately equal to 1:1.

12. The device of claim 10, wherein the at least one semiconductor die has a front surface opposite to the substrate and wherein the front surface lies at least approximately at the intermediate level.

13. The device of claim 10, wherein the substrate comprises a die pad of a leadframe including an array of electrically conductive leads around the die pad, and wherein the at least one electrically conductive via extends through the first and second portions of the encapsulation of LDS material from the outer surface of the encapsulation to at least one lead in the array of electrically conductive leads.

14. The device of claim 13, further comprising:
at least one frusto-conical electrically conductive via extending through the first portion of the encapsulation from the outer surface of the encapsulation to a front surface of the at least one semiconductor die; and
at least one linear electrically conductive formation extending at the outer surface of the encapsulation and coupling said at least one frusto-conical electrically conductive via and the enlarged collar section.

15. The device of claim 10, comprising:
at least one laser-ablated location of the encapsulation; and
metal material grown onto said at least one laser-ablated location.

16. The device of claim 15, wherein the metal material grown onto said at least one laser-ablated location comprises:
first metal material electroless grown onto said at least one laser-ablated location; and
second metal material electrolytically grown on the first metal material.

17. A method, comprising:
arranging at least one semiconductor die on a substrate;
molding an encapsulation of laser direct structuring (LDS) material onto the at least one semiconductor die arranged on the substrate, the encapsulation having an outer surface opposite the substrate;
applying a laser to form a first opening extending into the encapsulation from the outer surface, said first opening having a bottom surface with a first cross-sectional area;
applying a laser to form a second opening extending into the encapsulation from the bottom surface, said second opening having a first end at the bottom surface, wherein said first end has a second cross-sectional area smaller than the first cross-sectional area; and
growing metal material on sidewalls of the first and second openings and on the bottom of the first opening to form an electrically conductive via extending through the encapsulation.

18. The method of claim 17, wherein growing metal material comprises:
electroless growing first metal material at the first and second openings; and
electrolytic growing second metal material onto the first metal material.

19. The method of claim 17, wherein the first opening has a rectangular cross-section parallel to said outer surface and wherein the second opening has a circular cross-section parallel to said outer surface.

20. The method of claim 17, wherein an aspect ratio of the second opening is approximately equal to 1:1.

21. The method of claim 17, wherein a front surface of the at least one semiconductor die that is opposite to the substrate lies at approximately a same level as the bottom surface of the first opening.
